(19) United States
(12) Patent Application Publication
(10) Pub. No.: US 2001/0046787 A1
(43) Pub. Date: Nov. 29, 2001

(54) Method for forming a dielectric on a semiconductor substrate

(76) Inventors: Martin Kerber, Munchen (DE); Helmut Wurzer, Dresden (DE); Thomas Pompl, Altdorf (DE)

Correspondence Address: JENKINS & WILSON, PA, 3100 TOWER BLVD, SUITE 1400, DURHAM, NC, 27707, US

(21) Appl. No.: 09/836,946

(22) Filed: Apr. 18, 2001

(30) Foreign Application Priority Data
Apr. 20, 2000 (DE) 100 21 095.3

(51) Int. Cl. H01L 21/31

(52) U.S. Cl. 438/762; 438/763; 438/423

(57) ABSTRACT

The present invention provides a method for forming a dielectric 1; 7, 8 on a semiconductor substrate 2 having the following steps: implantation of ions into a surface layer of the semiconductor substrate 2, the ions forming a first dielectric layer 7; and performance of a thermal oxidation process for forming a second dielectric layer 8 on the first dielectric layer 7. Consequently, e.g. by the implantation of nitrogen ions into a surface layer of a silicon substrate, the imperfection density of the dielectric formed can be reduced approximately by a factor of 10.

The present invention relates to a method for forming a dielectric on a semiconductor substrate preferably in integrated circuits.

In the context of miniaturization in the field of electronics with the aim of producing extremely small electronic devices having the highest possible reliability and service life, which nevertheless contain a multiplicity of electronic components and switching elements, integrated circuits have played a dominant part for quite a long time. In this case, e.g. in the case of all field-effect components, a dielectric is the essential constitute part of the component which predetermines the service life of a chip. The reliability of a dielectric is in turn essentially characterized by its defect density or its imperfection density.

The following procedure is usually used to form a dielectric on a substrate.

Proceeding from a semiconductor substrate that is usually used, i.e. from the outset there are already different types of imperfections of specific density in the crystal, the surface thereof is cleaned by means of a special cleaning sequence. This cleaning sequence comprises, inter alia, the application of specially selected cleaning chemistry which is intended to be used to eliminate impurity particles on the surface of the substrate. This is followed by the formation of a dielectric layer on the substrate surface, e.g. an oxidation layer by means of a customary oxidation method.

Furthermore, the semiconductor substrates used may be what are referred to as “perfect substrates”, in which the imperfections are completely eliminated by means of complex methods actually during the production of the substrate, However, as a result of their complex production process, these “perfect substrates” are much too expensive and thus constitute an alternative with an economic disadvantage. Since the electronic components and switching elements are produced in large quantities, the part played by the cost factor is indeed just as important as that played by a simple and automated production method.

Consequently, it is more economic to use customary semiconductor substrates having a certain imperfection density as the starting material and to reduce the defect density in them by means of customary cleaning sequences.

The requirements made of e.g. such field-effect components are being raised higher and higher. Industry often requires of a chip a failure probability of a few 100 ppm with an average service life of 15 years, i.e. only an extremely small number of transistors overall are permitted to fail during the 15 years. The service life of a transistor in turn essentially depends on the purity of the dielectric, since a high imperfection density of the dielectric results in a higher probability of an electrical breakdown after a certain period of time. This reduction of this imperfections in the dielectric can greatly reduce the probability of an electrical breakdown and thus increase the service life of an individual component and switching element.

Since industry now aims to produce ever more complex chips with an ever greater number of transistors, for adherence to the service life of 15 years the probability of a defect of a transistor must be reduced in order, in this way, to maintain the absolute failure rate of transistors an a chip.

Consequently, it is an object of the present invention to provide a simple and cost-effective method enabling a dielectric to be applied on a semiconductor substrate with a lower imperfection density than according to the prior art.

This object is achieved by means of the method according to the invention having the features of claim 1.

The idea underlying the present invention consists in, for the purpose of forming a dielectric on a semiconductor substrate, firstly implanting ions into a surface layer of the semiconductor substrate, the ions forming a first dielectric layer; and afterward an oxidation process is performed for the purpose of forming a second dielectric layer on the first dielectric layer.

These method steps can result in a reduction in the imperfection density in the entire dielectric composed of the first dielectric later and the second dielectric layer.

In other words, a relatively thicker oxide is produced in the region of the defects by reducing the retarding effect of N atoms there.

Advantageous developments and improvements of the method specified in claim 1 can be found in the subclaims.

In accordance with a preferred refinement of the invention, the semiconductor substrate is preferably designed as a silicon substrate. Silicon has asserted itself as the most common wafer material in the meantime since it has particularly suitable electrical properties by comparison with other semiconductor materials.

In accordance with a further refinement, the implanted ions are nitrogen ions. As a result of the implantation of these nitrogen ions, a reduction in the imperfection density of the dielectric when using a silicon substrate approximately by a factor of 10 was ascertained, which means a reduction of the defect probability within the service life.

In accordance with a further preferred development, a cleaning process for cleaning the semiconductor substrate surface is performed before the dielectric is formed. This cleaning method is intended to already eliminate a large part of the defects such as e.g. impurity particles on the substrate surface, which adhere to the substrate in the course of the storage and transportation of said substrate.

In accordance with a further preferred refinement of the invention, the imperfections produced by the ion implantation are eliminated by means of a heat-treatment method before the thermal oxidation process. Every implantation method results in the formation of certain imperfections which increase the overall imperfection density. However, these imperfections produced by the ion implantation can easily be eliminated again from the crystal by means of a specific heat-treatment method.

According to a further preferred refinement, a screen layer for producing a predetermined penetration depth of the ions is produced before the implantation and is removed again after the implantation and still before the thermal oxidation process. This screen layer may be a natural oxide layer or an applied oxide layer. During the implantation process, a considerable number of detects are produced in this screen layer as well, principally as a result of applied impurity particles. Therefore, said screen layer is advantageously removed again from the substrate surface still before the thermal oxidation process.

Exemplary embodiments of the invention are illustrated in the drawings and explained in more detail in the description below. In the figures;

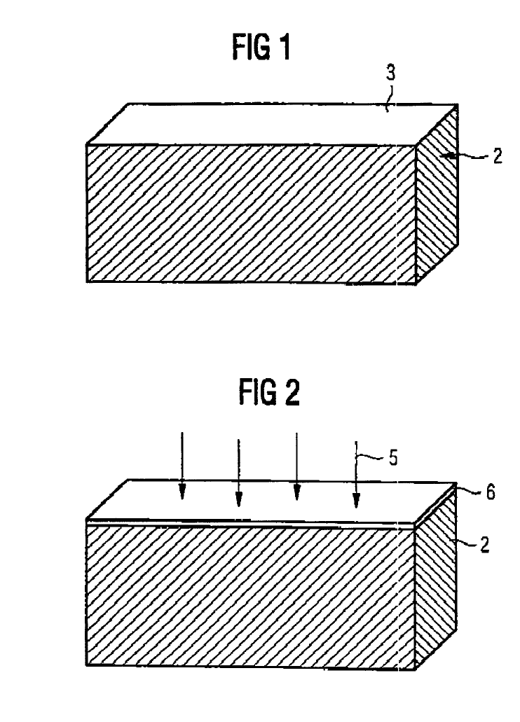

FIG. 1 shows a perspective view of a silicon substrate with a certain imperfection density in accordance with an exemplary embodiment of the present invention;

FIG. 2 shows a perspective view of the silicon substrate with applied screen layer during bombardment with nitrogen ions in accordance with the embodiment from FIG. 1;

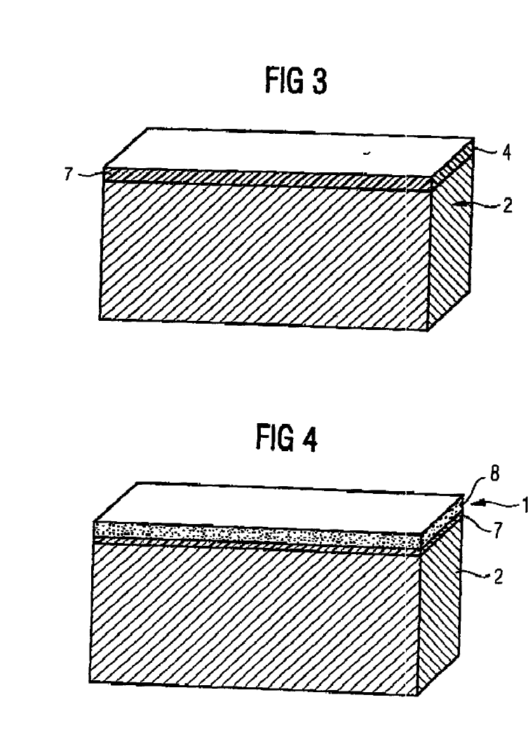

FIG. 3 shows a perspective view of the silicon substrate after the implantation of nitrogen ions with a first dielectric layer made of SiN in accordance with the exemplary embodiment from FIGS. 1 and 2; and

FIG. 4 shows a perspective view of a silicon substrate after a thermal oxidation process with a first dielectric layer made of SiN and a second dielectric layer made of SiO₂ in accordance with the exemplary embodiment of the present invention from FIGS. 1, 2 and 3.

FIG. 1 shows a customarily used silicon substrate 2 with a certain imperfection density. These imperfections may be in the form of contaminants on the surface of the semiconductor substrate and also in the form of defects on account of lattice dislocations, impurity atoms, etc., internally in the crystal. Proceeding from this silicon substrate 2, the intention, then, is to form, as described above, a dielectric 1 on top of the silicon substrate 2 in such a way that an electrically insulating layer 1 having specific electrical properties is produced between the semiconductor substrate 2 and e.g. a gate electrode. An improvement of this electrically insulating dielectric layer 1 is achieved through a reduction of the imperfection density prevailing in said layer. In order to produce a dielectric having the lowest possible imperfection density, proceeding from the semiconductor substrate illustrated in FIG. 1, the following procedure is adopted in accordance with a preferred embodiment of the present invention.

Firstly, the surface of the substrate 2 is thoroughly cleaned to remove contaminants. For this purpose, e.g. specially selected clearing chemistry is applied on the silicon substrate surface 3, which binds the impurity atoms, and is then removed again from the silicon substrate surface 3 together with the bound impurity atoms. In order to produce a predetermined penetration depth required for an ion implantation, a screen oxide layer 6 having a layer thickness of approximately 4.0 nm, as illustrated in FIG. 2, is subsequently applied on the silicon substrate surface 3. In order to produce nitrogen ions for a nitrogen ion beam 5, ammonia is sent through an ionization chamber, the gas molecules being ionized by field emission. Afterward, the nitrogen ions are extracted via a mass separator and accelerated to about 25 to 35 keV. Afterwards for implantation of the nitrogen ions, the nitrogen ion beam 5 is guided over the silicon substrate surface 3 with applied screen layer 6 until a desired dose of nitrogen ions has been reached in the substrate surface layer 4, which is monitored by the integration of the electric current.

By means of the implantation of the ions on the screen layer 6 on the silicon substrate surface 3, a penetration depth of the nitrogen ions in the silicon substrate 2 of approximately 30 to 50 nm can be produced.

The highest concentration of N atoms is situated at the surface, with the result that, as shown in FIG. 3, a first dielectric layer 7, comprising SiN, is formed in the surface layer 4 in the silicon substrate 2. As can be seen in FIG. 2, the screen layer 6 is removed from the silicon substrate surface 3 by means of a wet-chemical etching method directly after the end of the ion implantation process, since said screen layer is contaminated with impurity atoms in the course of the implantation method and thus has an excessively high imperfection density.

Furthermore, the implantation in the substrate surface layer 4 produces implantation defects in this layer 4. However, these undesirable imperfections can be removed from the silicon crystal 2 by means of an annealing method, a method step curing which the silicon wafer is kept at a high temperature (1000° C., 30 minutes).

A thermal oxidation process produces an oxide layer on the silicon substrate surface, the presence of N atoms on the surface impeding oxidation. Consequently, an oxide is produced which is somewhat thinner than would be produced under the same process conditions without N atoms. If a particle is situated on the surface or the surface currently intersects a vacancy agglomerate, then the density of N atoms is impeded less there and a thicker oxide is produced compared with oxide of the undisturbed substrate surface enriched by N atoms. As a result of this retardation of the oxidation in the undisturbed region and cancelation of the retarding effect in the region of imperfections, the breakdown voltage is increased in the region of the imperfections, with the result that they no longer act as defects of the dielectric.

The precondition for producing larger-area chins without increasing the failure probability is thus ensured.

The implanted nitrogen ions obviously ensure that the imperfections prevailing in the silicon substrate 2 are prepared in such a way that they oxidize more rapidly during the oxidation and thus form a thicker oxidation layer. Consequently, this defect site no longer constitutes a risk for an electrical breakdown.

Although the present invention has been described above using a preferred exemplary embodiment, it is not restricted thereto, but rather can be modified in diverse ways.

1. A method for forming a dielectric (1; 7, 8) on a semiconductor substrate (2) having the following steps:
a) implantation of ions (5) into a surface layer (4) of the semiconductor substrate (2), the ions (5) forming a first dielectric layer (7); and
b) performance of a thermal oxidation process for forming a second dielectric layer (8) on the first dielectric layer (7).

2. The method as claimed in claim 1, characterized
in that the semiconductor substrate (2) is preferably designed as a silicon substrate (2).

3. The method as claimed in claim 1 or 2, characterized
in that the implanted ions (5) are nitrogen ions (5).

4. The method as claimed in one of the preceding claims, characterized
in that a cleaning process for cleaning the semiconductor substrate surface (3) is performed before the dielectric (1; 7, 8) is formed.

5. The method as claimed in one of the preceding claims, characterized
in that the imperfections produced by the ion implantation are eliminated by means of a heat-treatment method before the thermal oxidation process.

6. The method as claimed in claim 1, characterized
in that the implanted ions inhibit the oxidation in the undisturbed region, but not in the region of defects, as a result of which an oxide is produced in the region of the defects, said oxide having a breakdown voltage which is at least as large as in the undisturbed region.

7. The method as claimed in one of the preceding claims, characterized
in that a screen layer (6) for producing a predetermined penetration depth of the ions (5) is produced before the implantation and is removed again after the implantation and still before the thermal oxidation process.
